(19) United States
(12) Patent Application Publication
(10) Pub. No.: US 2024/0315092 A1
(43) Pub. Date: Sep. 19, 2024

(54) DISPLAY PANELS AND METHODS FOR MANUFACTURING THE SAME

(71) Applicant: Shenzhen China Star Optoelectronics Semiconductor Display Technology Co., Ltd., Shenzhen (CN)

(72) Inventor: Qianyi ZHANG, Shenzhen (CN)

(73) Assignee: Shenzhen China Star Optoelectronics Semiconductor Display Technology Co., Ltd., Shenzhen (CN)

(21) Appl. No.: 18/542,681

(22) Filed: Dec. 17, 2023

(30) Foreign Application Priority Data
Mar. 13, 2023 (CN) 202310282420.2

(51) Int. Cl. H10K 59/126; H10K 59/12; H10K 59/121

(52) U.S. Cl. CPC H10K 59/126; H10K 59/1201; H10K 59/1216

(57) ABSTRACT

The present disclosure provides a display panel and a method for manufacturing the same. The display panel includes a functional metal layer that includes a capacitor plate, a light-shielding pattern, and a metal wiring disposed at intervals; areas where the capacitor plate, the light-shielding pattern, and the metal wiring are located are defined as a capacitance area, a light-shielding area, and a metal wiring area, respectively; a part of a buffer layer disposed in the capacitance area is provided with a first thinning structure; a first semiconductor is disposed on the first thinning structure and capable of forming a first capacitance with the capacitor plate.

### CROSS-REFERENCE TO RELATED APPLICATION

The present disclosure claims the priority to and benefit of Chinese Patent Application No. 202310282420.2, filed on Mar. 13, 2023, the disclosure of which is incorporated herein by reference in its entirety.

### TECHNICAL FIELD

The present disclosure relates to the field of display, and in particular, to display panels and methods for manufacturing the same.

### BACKGROUND

Organic light-emitting diodes (OLEDs) have the advantages of simple preparation process, low cost, high luminous efficiency, easy formation of flexible structures, low power consumption, high color saturation, and wide viewing angle, and the display technology using the OLEDs has become an important display technology.

OLED light-emitting materials for a display panel having high-resolution are generally deposited on an array substrate using the inkjet printing technology. The product evaluation test shows that the flatness of the array substrate is poor, which will lead to a decrease in luminous efficiency of OLED devices. If the array substrate uses thick Cu as metal wirings, film layers will be stacked in light-emitting opening areas, resulting in large terrain differences. Moreover, planarization materials cannot fill segment differences caused by the terrain differences, which is currently a major problem for the inkjet printing technology. Moreover, because the OLEDs are generally driven by 3T1C driving circuit, three thin film transistors and one capacitor, considering the uneven display brightness caused by the voltage drop (IR drop), thick Cu is generally used to prepare the wirings to reduce the IR drop for high pixels per inch (PPI) products. However, design rules of the processes for preparing the wirings made of thick Cu cannot meet the requirements of the high PPI products, resulting in low capacitance Cst.

Based on the above, in view of the problems of low capacitance and poor flatness of the array substrate existing in the existing display panel, the present disclosure provides a display panel to improve the problems from the source.

### SUMMARY

Embodiments of the present disclosure provide a display panel, including:

a substrate;

a functional metal layer disposed on the substrate and including a capacitor plate, a light-shielding pattern, and a metal wiring disposed at intervals, in which areas where the capacitor plate, the light-shielding pattern, and the metal wiring are located are defined as a capacitance area, a light-shielding area, and a metal wiring area, respectively;

a buffer layer disposed on the functional metal layer, in which a part of the buffer layer disposed in the capacitance area is provided with a first thinning structure; and

a semiconductor layer disposed on the buffer layer and including a first semiconductor disposed corresponding to the capacitor plate;

in which the first semiconductor is disposed on the first thinning structure and capable of forming a first capacitance with the capacitor plate.

Embodiments of the present disclosure further provide a display panel, including:

a substrate;

a functional metal layer disposed on the substrate and including a capacitor plate, a light-shielding pattern, and a metal wiring disposed at intervals, in which areas where the capacitor plate, the light-shielding pattern, and the metal wiring are located are defined as a capacitance area, a light-shielding area, and a metal wiring area, respectively;

a buffer layer disposed on the functional metal layer, in which a part of the buffer layer disposed in the capacitance area is provided with a first thinning structure;

a semiconductor layer disposed on the buffer layer and including a first semiconductor disposed corresponding to the capacitor plate, in which the first semiconductor is disposed on the first thinning structure and capable of forming a first capacitance with the capacitor plate;

an interlayer dielectric layer disposed on the semiconductor layer and including a second thinning structure disposed in the capacitance area; and

a source/drain electrode layer disposed on the interlayer dielectric layer and including a source/drain capacitor plate disposed in the capacitance area, in which the source/drain capacitor plate is disposed on the second thinning structure and capable of forming a second capacitance with the first semiconductor;

in which both of the first thinning structure and the second thinning structure are stepped grooves.

Embodiments of the present disclosure further provide a method for manufacturing a display panel, including:

providing a substrate;

forming a functional metal layer on the substrate and patterning to form a capacitor plate, a light-shielding pattern, and a metal wiring, in which areas where the capacitor plate, the light-shielding pattern, and the metal wiring are located are defined as a capacitance area, a light-shielding area, and a metal wiring area, respectively;

forming a buffer layer on the functional metal layer and forming a first thinning structure in a part of the buffer layer disposed in the capacitance area;

forming a semiconductor layer on the buffer layer and patterning to form at least a first semiconductor, in which the first semiconductor is disposed on the first thinning structure and capable of forming a first capacitance with the capacitor plate.

### BRIEF DESCRIPTION OF THE DRAWINGS

In order to explain technical solutions in embodiments of the present disclosure more clearly, the following will briefly introduce the drawings needed to be used in description of the embodiments. Apparently, the drawings in the following description are only some embodiments of the present disclosure. For ordinary skilled in the art, other drawings can be obtained from these drawings without paying creative effort.

FIG. 1 is a schematic structural diagram of a display panel provided by some embodiments of the present disclosure.

FIGS. 2A to 2G are schematic diagrams of structures in a method for manufacturing a display panel provided by some embodiments of the present disclosure.

### DETAILED DESCRIPTION

The descriptions of each of the following embodiments are with reference to the attached drawings to illustrate specific embodiments that can be used to be implemented in the present disclosure. Directional terms mentioned in the present disclosure, such as [upper], [lower], [front], [rear], [left], [right], [inner], [outer], [side], and the like, refer only to the direction of the additional drawings. Therefore, the directional terms used are intended to illustrate and understand the present disclosure and not to limit it. In the drawings, units with similar structures are represented by the same numeral.

The following is a further explanation of the present disclosure in conjunction with the attached drawings and specific embodiments.

Embodiments of the present disclosure provide a display panel and a manufacturing method thereof, which can solve problems of low capacitance of display panels and poor flatness of array substrates from the source.

As shown in FIG. 1, the display panel includes a substrate 11 and a functional metal layer 12 disposed on the substrate 11. The functional metal layer 12 includes a capacitor plate 121, a light-shielding pattern 122, and a metal wiring 123 disposed at intervals. Areas where the capacitor plate 121, the light-shielding pattern 122, and the metal wiring 123 are located are defined as a capacitance area 101, a light-shielding area 102, and a metal wiring area 103, respectively.

Specifically, a thickness of the functional metal layer 12 ranges from 6500 Å to 10000 Å. In some embodiments, a material of the functional metal layer 12 is Cu or an alloy including Cu. In some embodiments, the functional metal layer 12 may be a three-layer structure, which includes an upper layer being a contact enhancement layer that contains an alloy including one or more of Mo, Ti, and Ni, a middle layer being a main metal wiring layer containing Cu or an alloy including Cu, and a lower layer being an oxidation protection layer to avoid oxidation failure of the main metal wiring layer in processes of an array substrate in the display panel. The oxidation protection layer contains an alloy including one or more of Mo, Ti, and Ni. It should be noted that the present disclosure does not specifically limit the material of the functional metal layer 12.

A buffer layer 13 is disposed on the functional metal layer 12, and a thickness of the buffer layer 13 ranges from 3000 Å to 5000 Å. A part of the buffer layer 13 disposed in the capacitance area 101 is provided with a first thinning structure 41, which reduces the thickness of the buffer layer 13 disposed in the capacitance area 101. Specifically, a depth of the first thinning structure 41 is ⅕-¼ of the thickness of the buffer layer 13, that is, a thinning thickness of the buffer layer 13 is ⅕-¼ of an initial thickness. A part of the buffer layer 13 disposed in the metal wiring area 103 is provided with a first via hole 51. Specifically, in the capacitance area 101, a width of the first thinning structure 41 is at least greater than or equal to a width of the capacitor plate 121; and in the metal wiring area 103, a width of the first via hole 51 is less than a width of the metal wiring 123.

The semiconductor layer 14 is disposed on the functional metal layer 12, and a thickness of the semiconductor layer 14 ranges from 200 Å to 400 Å. A material of the semiconductor layer 14 includes, but not limited to, indium gallium zinc oxide (IGZO), indium gallium tin oxide (IGTO), or indium gallium zinc tin oxide (IGZTO).

The semiconductor layer 14 includes a first semiconductor 141 disposed corresponding to the capacitor plate 121. The first semiconductor 141 is disposed on the first thinning structure 41 and forms a first capacitance with the capacitor plate 121.

It should be noted that the setting of the first thinning structure 41, on the one hand, reduces the thickness of the buffer layer 13 in the capacitance area 101, which can significantly increase capacitance; on the other hand, it can reduce the overall height of the display panel in the capacitance area 101, thus reducing the terrain differences, and improving flatness. Further, the first thinning structure 41 is a stepped groove having at least one step. In the embodiments as illustrated in FIG. 1, the first thinning structure 41 is a stepped groove having one step. In some preferred embodiments, the first thinning structure 41 may be a multi-step stepped groove, which can realize terrain buffering and is more conducive to improving the flatness compared to the stepped groove having one step.

Continuing to refer to FIG. 1, the semiconductor layer 14 also includes a second semiconductor 142 and a third semiconductor 143 disposed corresponding to the light-shielding pattern 122 and the metal wiring 123, respectively. The second semiconductor 142 includes a channel area 1421 and source/drain lap-jointed areas 1422 disposed at two sides of the channel area 1421. The third semiconductor 143 is in direct contact with the metal wiring 123 through the first via hole 51, and covers a bottom and a side wall of the first via hole 51.

Further, a gate insulation layer 15 and a gate 16 are stacked on the second semiconductor 142 disposed in the channel area 1421.

Further, an interlayer dielectric layer 17 is disposed on the semiconductor layer 14, and provided with a second via hole 52 disposed in the metal wiring area 103, a third via hole 53 and a fourth via hole 54 disposed in the light-shielding area 102, and a second thinning structure 42 disposed in the capacitance area 101. It should be noted that a width of the second via hole 52 is less than a width of the third semiconductor 143. The third via hole 53 and the fourth via hole 54 are disposed in the source/drain lap-jointed areas 1422 of the second semiconductor 142. The second thinning structure 42 thins the interlayer dielectric layer 17 disposed in the capacitance area 101. Specifically, a depth of the second thinning structure 42 is ¼-½ of an initial thickness of the interlayer dielectric layer 17, that is, a thinning thickness of the interlayer dielectric layer 17 is ¼-½ of the initial thickness. A width of the second thinning structure 42 is greater than or equal to a width of the first semiconductor 141. Further, the second thinning structure 42 is a stepped groove having at least one step. In the embodiments as illustrated in FIG. 1, the second thinning structure 42 is a stepped groove having one step. In some preferred embodiments, the second thinning structure 42 is a multi-step stepped groove, which can achieve terrain buffering and is more conducive to improving flatness compared to the stepped groove having one step.

Continuing to refer to FIG. 1, a source/drain electrode layer 18 is disposed on the interlayer dielectric layer 17. In some preferred embodiments, the source/drain electrode layer 18 is a two-layer structure, which includes a lower layer being a contact enhancement layer containing an alloy including one or more of Mo, Ti, and Ni, and an upper layer being a main metal wiring layer containing Cu or an alloy including Cu. The source/drain electrode layer 18 includes a source/drain electrode wiring 181 disposed in the metal wiring area 103, a source 182 and a drain 183 disposed in the light-shielding area 102, and a source/drain capacitor plate 184 disposed in the capacitance area 101. The source/drain capacitor plate 184 is disposed on the second thinning structure 42 and forms a second capacitance with the first semiconductor 141. Because the thickness of the interlayer dielectric layer 17 of the capacitance area 101 is reduced, the overall height of the capacitance area 101 can be reduced and the flatness can be improved while the capacitance is significantly increased.

Further, the source 182 and the drain 183 are connected to the source/drain lap-jointed areas 1422 of the second semiconductor 142 through the third via hole 53 and the fourth via hole 54, respectively. The source/drain electrode wiring 181 is connected to the third semiconductor 143 through the second via hole 52.

Continuing to refer to FIG. 1, the display panel also includes a passivation layer 19, a planarization layer 20, an anode layer 21, and a pixel definition layer 22 sequentially stacked on the source/drain electrode layer 18. Specifically, the passivation layer 19 and the planarization layer 20 are provided with a fifth via hole 55, and the anode layer 21 is connected to the drain 183 through the fifth via hole 55. The pixel definition layer 22 is patterned to form an opening part disposed in the light-shielding area 102.

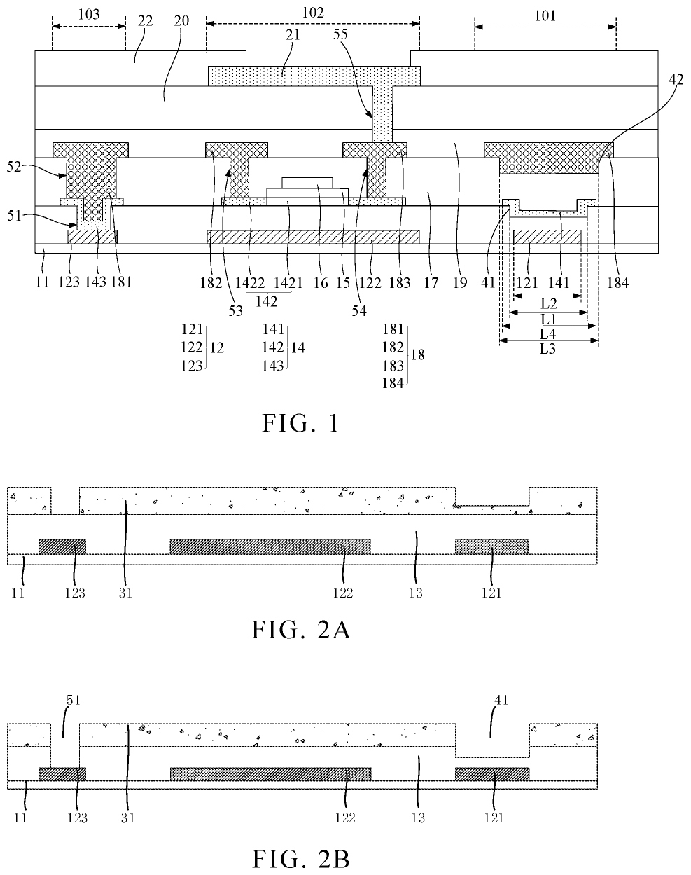

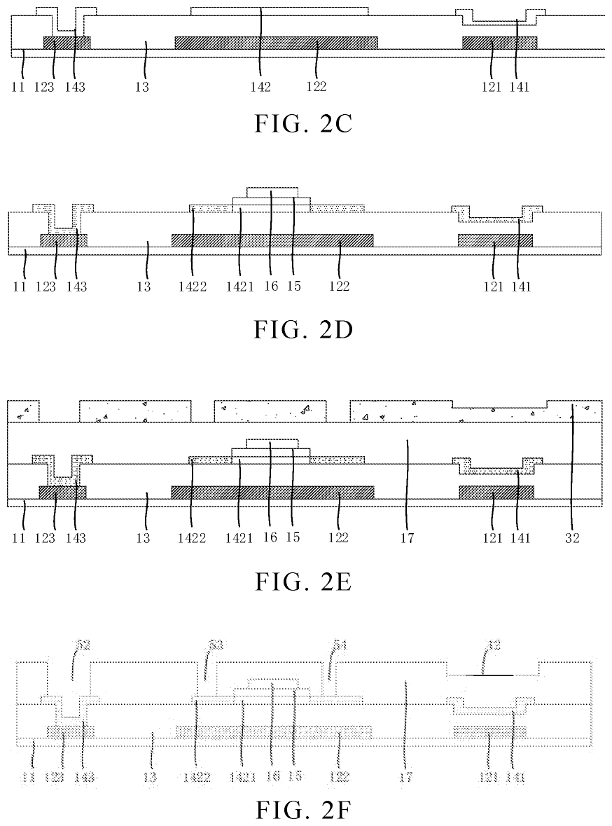

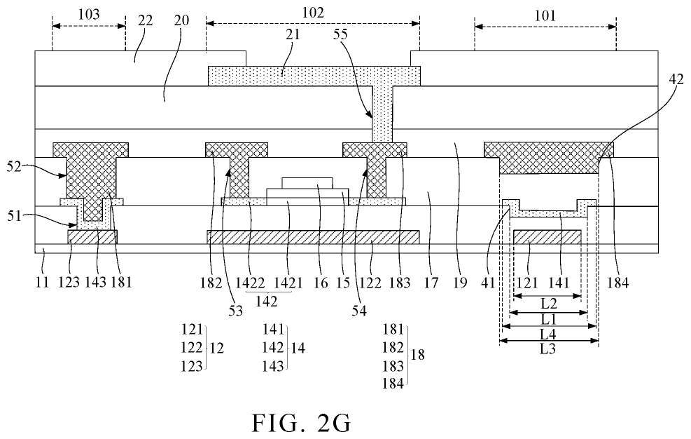

Embodiments of the present disclosure further provide a method for manufacturing a display panel for preparing the above-mentioned display panel. Referring to FIG. 1 and FIGS. 2A to 2G, the manufacturing method includes following steps S1 to S8.

In step S1, the substrate 11 is provided.

In step S2, the functional metal layer 12 is formed on the substrate 11, and patterned to form the capacitor plate 121, the light-shielding pattern 122, and the metal wiring 123. The areas where the capacitor plate 121, the light-shielding pattern 122, and the metal wiring 123 are located are defined as the capacitance area 101, the light-shielding area 102, and the metal wiring area 103, respectively. Specifically, the thickness of the functional metal layer 12 ranges from 6500 Å to 10000 Å.

In step S3, the buffer layer 13 is formed on the functional metal layer 12, and the first via hole 51 and the first thinning structure 41 are formed on the buffer layer 13 by a semi-transparent photolithography process. The first via hole 51 is disposed in the metal wiring area 103, and the first thinning structure 41 is disposed in the capacitance area 101.

Specifically, as shown in FIG. 2A and FIG. 2B, a first photoresist 31 is formed on the functional metal layer 12 and performed on semi-transparent exposure. The first photoresist 31 disposed in the metal wiring area 103 is performed on full transparent development, the first photoresist 31 disposed in the capacitance area 101 is performed on semi-transparent development, and the first photoresist 31 disposed in the light-shielding area 102 is performed on an opaque treatment. The buffer layer 13 disposed in the metal wiring area 103 is etched to form the first via hole 51 by a dry etching process, and then the first photoresist 31 is thinned by an ashing process, making the thickness of the buffer layer 13 disposed in the capacitance area 101 thinner. The thinning thickness of the buffer layer 13 disposed in the capacitance area 101 is ⅕-¼ of the initial thickness to form the first thinning structure 41. After completing the semi-transparent photolithography process, the first photoresist 31 is peeled off.

In some preferred embodiments, the dry etching process uses an inductively coupled plasma (ICP) mode, in which a pressure ranges from 10 mt to 30 mt, a power ranges from 400 W to 1000 W, and a time ranges from 10 seconds to 20 seconds.

In step S4, the semiconductor layer 14 is formed on the buffer layer 13, and patterned to form the first semiconductor 141, the second semiconductor 142, and the third semiconductor 143; the first semiconductor 141 is disposed on the first thinning structure 41 and forms the first capacitance with the capacitor plate 121; the second semiconductor 142 includes the channel area 1421 and the source/drain lap-jointed areas 1422 disposed at two sides of the channel area 1421; and the third semiconductor 143 is lap-jointed with the metal wiring 123 through the first via hole 51, as shown in FIG. 2C.

In step S5, the first semiconductor 141, the source/drain lap-jointed areas 1422 of the second semiconductor 142, and the third semiconductor 143 are performed on a conducting treatment, then the gate insulation layer 15 and the patterned gate 16 are formed on the channel area 1421 of the second semiconductor 142, as shown in FIG. 2D.

In step S6, the interlayer dielectric layer 17 is formed on the semiconductor layer 14, and the second via hole 52 disposed in the metal wiring area 103, the third via hole 53 and the fourth via hole 54 disposed in the light-shielding area 102, and the second thinning structure 42 disposed in the capacitance area 101 are formed on the interlayer dielectric layer 17 through a semi-transparent photolithography process.

Specifically, as shown in FIG. 2E and FIG. 2F, a second photoresist 32 is formed on the interlayer dielectric layer 17 and performed on semi-transparent exposure. The second photoresist 32 disposed in the metal wiring area 103 and the source/drain lap-jointed areas 1422 of the light-shielding area 102 are performed on full transparent development, the second photoresist 32 disposed in the capacitance area 101 is performed on semi-transparent development, and the second photoresist 32 disposed in the remaining areas is performed on an opaque treatment. The interlayer dielectric layer 17 disposed in the metal wiring area 103 is etched to form the second via hole 52 by a dry etching process, and the interlayer dielectric layer 17 disposed in the source/drain lap-jointed areas 1422 is etched to form the third via hole 53 and the fourth via hole 54 by a dry etching process. Subsequently, the second photoresist 32 is thinned by an ashing process, making the thickness of the interlayer dielectric layer 17 disposed in the capacitance area 101 thinner. The thinning thickness of the interlayer dielectric layer 17 disposed in the capacitance area 101 is ¼-½ of the initial thickness to form the second thinning structure 42. After completing the semi-transparent photolithography process, the second photoresist 32 is peeled off.

In some preferred embodiments, the dry etching process uses the ICP mode, in which a pressure ranges from 10 mt to 30 mt, a power ranges from 1000 W to 2000 W, and a time ranges from 10 seconds to 20 seconds.

In step S7, the source/drain electrode layer 18 is formed on the interlayer dielectric layer 17, and includes the source/drain electrode wiring 181 disposed in the metal wiring area 103, the source 182 and the drain 183 disposed in the light-shielding area 102, and the source/drain capacitor plate 184 disposed on the second thinning structure 42; the source/drain capacitor plate 184 and the first semiconductor 141 form the second capacitance, as shown in FIG. 2G.

Further, the source 182 and the drain 183 are connected to the source/drain lap-jointed areas 1422 of the second semiconductor 142 through the third via hole 53 and the fourth via hole 54, respectively. The source/drain electrode wiring 181 is connected to the third semiconductor 143 through the second via hole 52.

In step S8, the passivation layer 19, the planarization layer 20, the anode layer 21, and the pixel definition layer 22 are sequentially stacked on the source/drain electrode layer 18, as shown in FIG. 2G.

Specifically, the passivation layer 19 and the planarization layer 20 are provided with the fifth via hole 55, and the anode layer 21 is connected to the drain 183 through the fifth via hole 55. The pixel definition layer 22 is patterned to form the opening part disposed in the light-shielding area 102.

In the context, the present disclosure provides the display panel and the method for manufacturing the same. The display panel includes the functional metal layer including the capacitor plate, the light-shielding pattern, and the metal wiring disposed at intervals; the areas where the capacitor plate, the light-shielding pattern, and the metal wiring are located are defines as the capacitance area, the light-shielding area, and the metal wiring area, respectively; a part of the buffer layer disposed in the capacitance area is provided with the first thinning structure to reduce the thickness of the buffer layer disposed in the capacitance area; the first semiconductor is disposed on the first thinning structure and forms the first capacitance with the capacitor plate. The present disclosure, by reducing the thickness of the buffer layer disposed in the capacitance area, on the one hand, significantly increases capacitance, and on the other hand, reduces the overall height of the capacitance area, thereby improving flatness. Further, by designing grooves in the buffer layer, deep grooves can be avoided in subsequent processes, thereby improving yield of the etching processes.

Based on the above, although the present disclosure is disclosed as described above with preferred embodiments. The above preferred embodiments are not intended to limit the present disclosure, and those skilled in the art can make various changes and embellishments without departing from the spirit and idea of the present disclosure, so the scope of protection of the present disclosure is based on the claims.

What is claimed is:

1. A display panel comprising:
a substrate;
a functional metal layer disposed on the substrate and comprising a capacitor plate, a light-shielding pattern, and a metal wiring disposed at intervals, wherein areas where the capacitor plate, the light-shielding pattern, and the metal wiring are located are defined as a capacitance area, a light-shielding area, and a metal wiring area, respectively;
a buffer layer disposed on the functional metal layer, wherein a part of the buffer layer disposed in the capacitance area is provided with a first thinning structure; and
a semiconductor layer disposed on the buffer layer and comprising a first semiconductor disposed corresponding to the capacitor plate;
wherein the first semiconductor is disposed on the first thinning structure and capable of forming a first capacitance with the capacitor plate.

2. The display panel of claim 1, wherein the semiconductor layer further comprises a second semiconductor and a third semiconductor disposed corresponding to the light-shielding pattern and the metal wiring, respectively;
the second semiconductor comprises a channel area and source/drain lap-jointed areas disposed at two sides of the channel area; and
a part of the buffer layer disposed in the metal wiring area is provided with a first via hole, and the third semiconductor is in direct contact with the metal wiring through the first via hole.

3. The display panel of claim 2, further comprising a gate insulation layer and a gate stacked in the channel area of the second semiconductor.

4. The display panel of claim 2, further comprising an interlayer dielectric layer disposed on the semiconductor layer, wherein the interlayer dielectric layer is provided with a second via hole disposed in the metal wiring area, a third via hole and a fourth via hole disposed in the light-shielding area, and a second thinning structure disposed in the capacitance area.

5. The display panel of claim 4, further comprising a source/drain electrode layer disposed on the interlayer dielectric layer, wherein the source/drain electrode layer comprises a source/drain electrode wiring disposed in the metal wiring area, a source and a drain disposed in the light-shielding area, and a source/drain capacitor plate disposed in the capacitance area; and
wherein the source/drain capacitor plate is disposed on the second thinning structure and capable of forming a second capacitance with the first semiconductor.

6. The display panel of claim 5, further comprising a passivation layer, a planarization layer, an anode layer, and a pixel definition layer disposed on the source/drain electrode layer in stack.

7. The display panel of claim 1, wherein the first thinning structure is a stepped groove having at least one step.

8. The display panel of claim 7, wherein a depth of the first thinning structure is ⅕-¼ of an initial thickness of the buffer layer.

9. The display panel of claim 1, wherein a width of the first thinning structure is greater than or equal to a width of the capacitor plate.

10. The display panel of claim 1, further comprising:
an interlayer dielectric layer disposed on the semiconductor layer and comprising a second thinning structure disposed in the capacitance area; and
a source/drain electrode layer disposed on the interlayer dielectric layer and comprising a source/drain capacitor plate disposed in the capacitance area;
wherein the source/drain capacitor plate is disposed on the second thinning structure and capable of forming a second capacitance with the first semiconductor.

11. The display panel of claim 10, wherein the second thinning structure is a stepped groove having at least one step.

12. The display panel of claim 10, wherein a depth of the second thinning structure is ¼-½ of an initial thickness of the interlayer dielectric layer.

13. The display panel of claim 10, wherein a width of the second thinning structure is greater than or equal to a width of the first semiconductor.

14. The display panel of claim 10, wherein both of the first thinning structure and the second thinning structure are stepped grooves.

15. The display panel of claim 10, wherein a depth of the first thinning structure is ⅕-¼ of an initial thickness of the buffer layer, and a depth of the second thinning structure is ¼-½ of an initial thickness of the interlayer dielectric layer.

16. A display panel comprising:
a substrate;
a functional metal layer disposed on the substrate and comprising a capacitor plate, a light-shielding pattern, and a metal wiring disposed at intervals, wherein areas where the capacitor plate, the light-shielding pattern, and the metal wiring are located are defined as a capacitance area, a light-shielding area, and a metal wiring area, respectively;
a buffer layer disposed on the functional metal layer, wherein a part of the buffer layer disposed in the capacitance area is provided with a first thinning structure;
a semiconductor layer disposed on the buffer layer and comprising a first semiconductor disposed corresponding to the capacitor plate, wherein the first semiconductor is disposed on the first thinning structure and capable of forming a first capacitance with the capacitor plate;
an interlayer dielectric layer disposed on the semiconductor layer and comprising a second thinning structure disposed in the capacitance area; and
a source/drain electrode layer disposed on the interlayer dielectric layer and comprising a source/drain capacitor plate disposed in the capacitance area, wherein the source/drain capacitor plate is disposed on the second thinning structure and capable of forming a second capacitance with the first semiconductor;
wherein both of the first thinning structure and the second thinning structure are stepped grooves.

17. The display panel of claim 16, wherein a width of the first thinning structure is greater than or equal to a width of the capacitor plate, and a width of the second thinning structure is greater than or equal to a width of the first semiconductor.

18. The display panel of claim 16, wherein the semiconductor layer further comprises a second semiconductor and a third semiconductor disposed corresponding to the light-shielding pattern and the metal wiring, respectively;
the second semiconductor comprises a channel area and source/drain lap-jointed areas disposed at two sides of the channel area; and
wherein a part of the buffer layer disposed in the metal wiring area is provided with a first via hole, and the third semiconductor is in direct contact with the metal wiring through the first via hole.

19. A method for manufacturing a display panel comprising:
providing a substrate;
forming a functional metal layer on the substrate and patterning to form a capacitor plate, a light-shielding pattern, and a metal wiring, wherein areas where the capacitor plate, the light-shielding pattern, and the metal wiring are located are defined as a capacitance area, a light-shielding area, and a metal wiring area, respectively;
forming a buffer layer on the functional metal layer and forming a first thinning structure in a part of the buffer layer disposed in the capacitance area; and
forming a semiconductor layer on the buffer layer and patterning to form at least a first semiconductor, wherein the first semiconductor is disposed on the first thinning structure and capable of forming a first capacitance with the capacitor plate.

20. The method for manufacturing the display panel of claim 19, wherein the step of forming the first thinning structure in the part of the buffer layer disposed in the capacitance area comprises:
forming a first photoresist on the buffer layer and performing semi-transparent exposure; and
performing full transparent development on the first photoresist disposed in the metal wiring area, performing semi-transparent development on the first photoresist disposed in the capacitance area, and performing an opaque treatment on the first photoresist disposed in the light-shielding area; wherein a part of the buffer layer disposed in the capacitance area forms the first thinning structure.
